(19) United States
(12) Patent Application Publication
(10) Pub. No.: US 2024/0242740 A1
(43) Pub. Date: Jul. 18, 2024

(54) DUAL IN-LINE MEMORY MODULE RETAINER

(71) Applicant: Intel Corporation, Santa Clara, CA (US)

(72) Inventors: Phil GENG, Washougal, WA (US); Xiang LI, Portland, OR (US); George VERGIS, Portland, OR (US)

(21) Appl. No.: 18/622,813

(22) Filed: Mar. 29, 2024

(51) Int. Cl. G11C 5/04; H05K 1/14; H05K 1/18

(52) U.S. Cl. CPC G11C 5/04; H05K 1/141; H05K 1/181; H05K 2201/10159; H05K 2201/10189

(57) ABSTRACT

A retainer to inhibit movement of dual in-line memory modules (DIMMs) that are removably inserted into connectors attached to a printed circuit board (PCB) of a system. Inhibiting movement of the DIMMs, especially taller DIMMs, such as the higher height 2 U and 4 U DIMMs, mitigates the effects of operational vibration causing intermittent electrical discontinuity between DIMM and the PCB. The retainer inhibits movement of DIMMs at the connector component level by constraining all or a portion of top edges of DIMMs inserted into connectors. The retainer is implemented independently of the design of the system-level chassis. The retainer is shaped into any of a bracket or frame from multiple rigid horizontal, vertical and oblique members that permit airflow to the DIMMs and connectors retained therein.

### FIELD

This disclosure relates to connectors for coupling dual in-line memory module devices (DIMMs) with a printed circuit board (PCB) and, more particularly, to retaining DIMMs inserted into connectors to reduce unwanted device movement.

### BACKGROUND

Various technologies exist for connecting devices, such as dual in-line memory modules (DIMMs), with a printed circuit board (PCB), such as a motherboard (MB). While it is possible to couple electronic components directly to a PCB, it is common to use a connector between the PCB and a DIMM to enable removably coupling the DIMM with the PCB.

One challenge to removably coupling a DIMM using connectors mounted onto the PCB is the high dynamic risk of DIMM movement during operation. DIMM movement can lead to intermittent electrical discontinuity between the DIMM and the PCB.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” are to be understood as describing at least one implementation of the invention that includes one or more particular features, structures, or characteristics. Thus, phrases such as “in one embodiment” or “in an alternate embodiment” appearing herein describe various embodiments and implementations of the invention, and do not necessarily all refer to the same embodiment. However, they are also not necessarily mutually exclusive.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

It is noted that the views, block diagrams and the like in the drawings are illustrative and not drawn to scale. For example, the relative dimensions and placements for some of the components in the views and block diagrams herein are exaggerated for clarity and point of illustration. For example, one having skill in the art will recognize the components in an actual implementation will generally have dimensions and thicknesses that are different than that shown in the Figures herein (e.g., substantially smaller and/or thinner), or be placed in a manner that is different from what is represented in a block diagram or other illustration.

FIG. 1A is a front view of an example of a chassis system in which a DIMM retainer can be implemented in accordance with embodiments described herein;

FIG. 1B is a side view of the example in FIG. 1A;

FIGS. 2A-2B illustrate a DIMM retainer attached to a connector in accordance with embodiments described herein;

FIGS. 3A-3B illustrate another DIMM retainer attached to a connector in accordance with embodiments described herein;

FIGS. 4A-4B illustrate yet another DIMM retainer attached to a connector in accordance with embodiments described herein;

FIGS. 5A-5B illustrate a tabbed connector in accordance with embodiments described herein;

FIGS. 6A-6B illustrate a DIMM retainer attached to a tabbed connector in accordance with embodiments described herein;

FIGS. 7A-7B illustrate another DIMM retainer attached to a tabbed connector in accordance with embodiments described herein;

FIGS. 8A-8D illustrate various cutouts for a DIMM retainer in accordance with embodiments described herein;

FIGS. 9A-9B are flow diagrams illustrating example processes for implementing a DIMM retainer in accordance with embodiments described herein; and

FIG. 10 depicts a system in which a DIMM retainer may be implemented in accordance with embodiments described herein.

### DETAILED DESCRIPTION

Conventional connectors, such as Double Data Rate Version 5 (DDR5) connectors formed in accordance with memory technology standard specifications originally published by JEDEC (Joint Electronic Device Engineering Council) in October 2013, or with other technologies based on derivatives or extensions of such specifications, are designed connect a device, such as a dual in-line memory module (DIMM), to a PCB in such a way that the device is electrically coupled to the PCB but also removable. During operation, taller devices, such as tall DIMMs (e.g., double rack unit DIMMs, or 2 U DIMMs, and higher, used in rack unit servers of various heights and widths), have an especially high dynamic risk of device movement along the lateral DIMM direction.

For example, a tall 2 U DIMM that is used in a rack unit server has a height of 58 mm. When inserted into a standard connector, operational vibration tests using a 50 g dummy card reveal electric discontinuity>1 μs. This failure is caused by the DIMM lateral movement during operational vibration.

Existing mitigation efforts include chassis-based system level device retention. For example, the chassis system is typically designed with a top cover to hold the DIMMs in place. While effective at reducing DIMM lateral movement, the chassis system approach requires custom designing the chassis around the placement of the connectors into which the DIMMs are inserted. The chassis system-level approach makes standardized DIMM retention design difficult due to system variations.

Another mitigation effort at the DIMM connector component level is to add a latch/constraint to the sides of the connector into which DIMMs are inserted. However, even when the additional latch/constraint is used on the sides of the connector, the upper side and top edges of DIMMs, especially the taller 2 U DIMMs, are not constrained, and lateral movement of a DIMM can still occur during operational vibration.

To address this challenge, a DIMM retainer in accordance with embodiments described herein constrains a top edge of one or more DIMMs inserted into the connectors. The retainer inhibits movement of DIMMs inserted into the connectors during operation of the system to minimize electric discontinuity. The DIMMs that can be retained include both regular and tall DIMMS, such as 2 U, 4 U and higher height DIMMs.

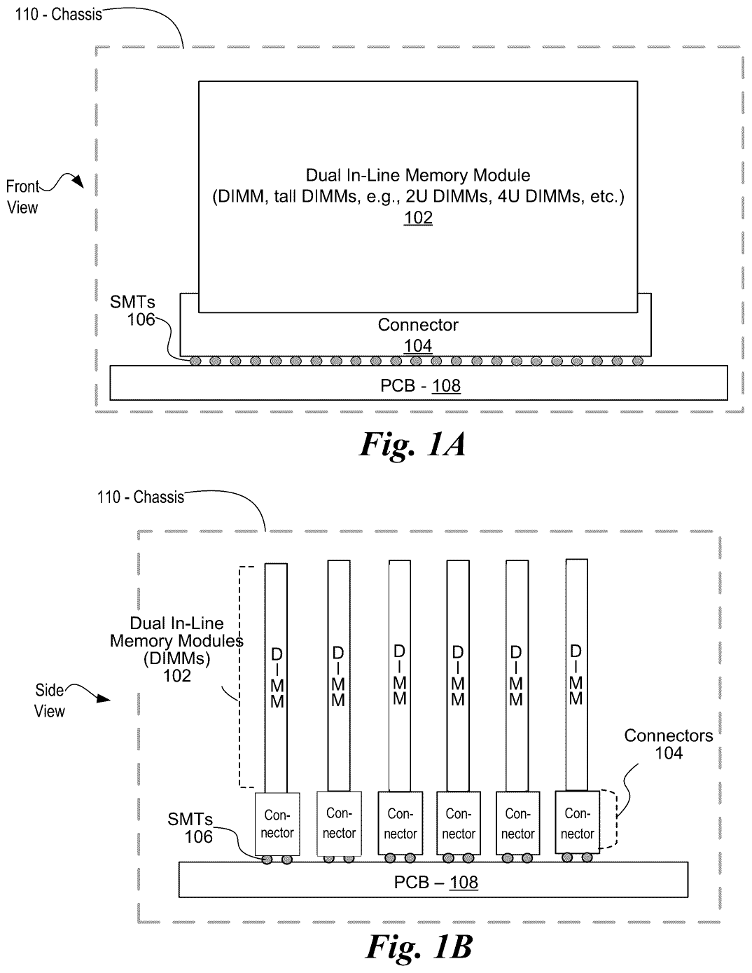

FIG. 1A illustrates selected components of a system in which a DIMM retainer can be implemented in accordance with embodiments described herein. As shown in a front view of the system, a chassis encases a connector 104 coupled with a printed circuit board (PCB) 108 (such as a motherboard). The connector 104 includes pins (not shown) that are in physical and electrical contact with the PCB 108 via surface-mounted technology pads (SMTs) 106 (e.g., a solder pad) disposed on the surface of the PCB 108. When a DIMM 102, such as a 2 U DIMM, is inserted into the connector 104, the DIMM 102 is in electrical contact with the PCB 108.

FIG. 1B illustrates a side view of the selected components of the system described in FIG. 1A. As shown, multiple adjacent connectors 104 are positioned atop the PCB 108 and SMTs 106. Inserted into each connector 104 is a DIMM 102 to make an electrical connection with the PCB 108. Multiple DIMMs 102 are inserted into respective multiple adjacent connectors 104.

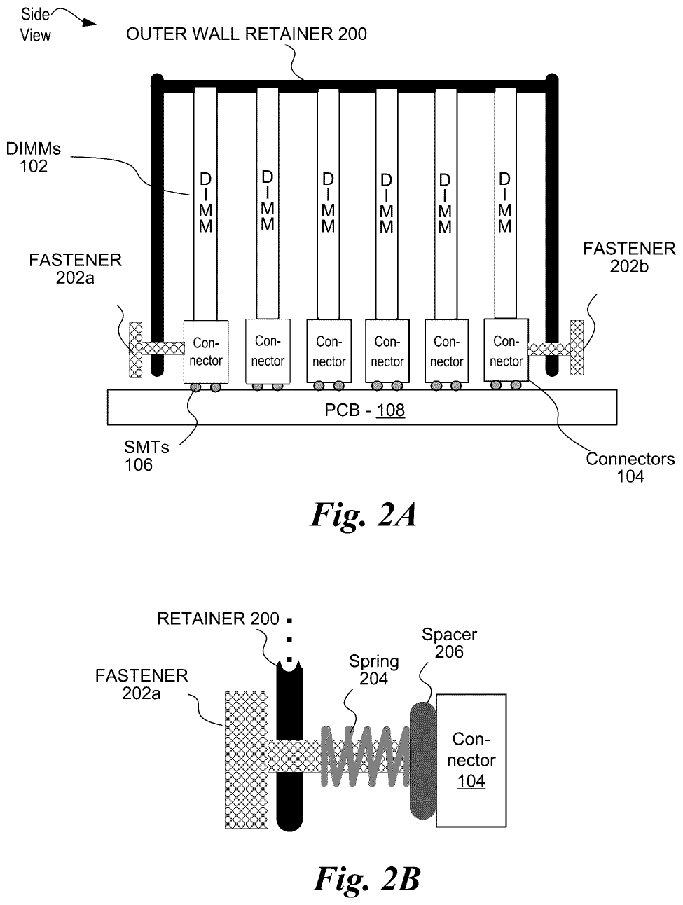

FIG. 2A illustrates an embodiment of a retainer 200 formed in accordance with embodiments described herein. As shown, the retainer 200 includes two vertical members and one horizontal member joined together to form a U-shaped bracket. In one embodiment, the retainer 200 and all of the subsequent variations of the retainer disclosed in the paragraphs that follow can be comprised of a steel or plastic material having sufficient rigidity to constrain DIMMs 102 inserted into connectors 104 as described herein.

The illustrated retainer in FIG. 2A is referred to as an outer wall retainer 200 because the vertical members attach to the outer surfaces of the outermost connectors 104 that delimit multiple adjacent connectors 104. In this manner the horizontal member of retainer 200 extends over at least a portion of the top edges of each of the DIMMs 102 inserted into the connectors 104 to constrain the top edges, thereby inhibiting movement of the DIMMs 102 inserted into the connectors 104 during operation of the system.

In one embodiment, the retainer 200 is attached to the outer surfaces of the outermost connectors 104 using fasteners 202a/202b. FIG. 2B illustrates one example of a fastener 202a that can be used to attach the retainer 200 to the connector 104. In this example, the fastener 202a is a threaded screw capable of tightening a spring compressive pin 204 against a spacer 206 adjoining the outer surface of the connector in the desired attachment location. Other types of fasteners could be used as well.

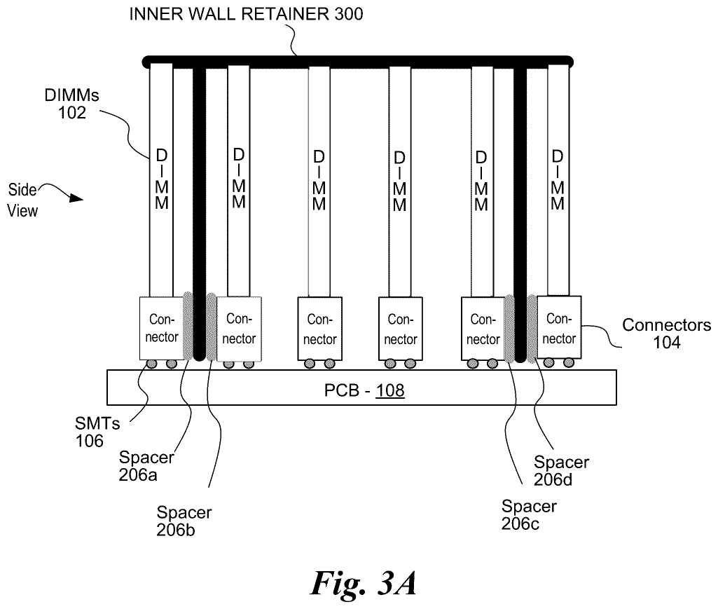

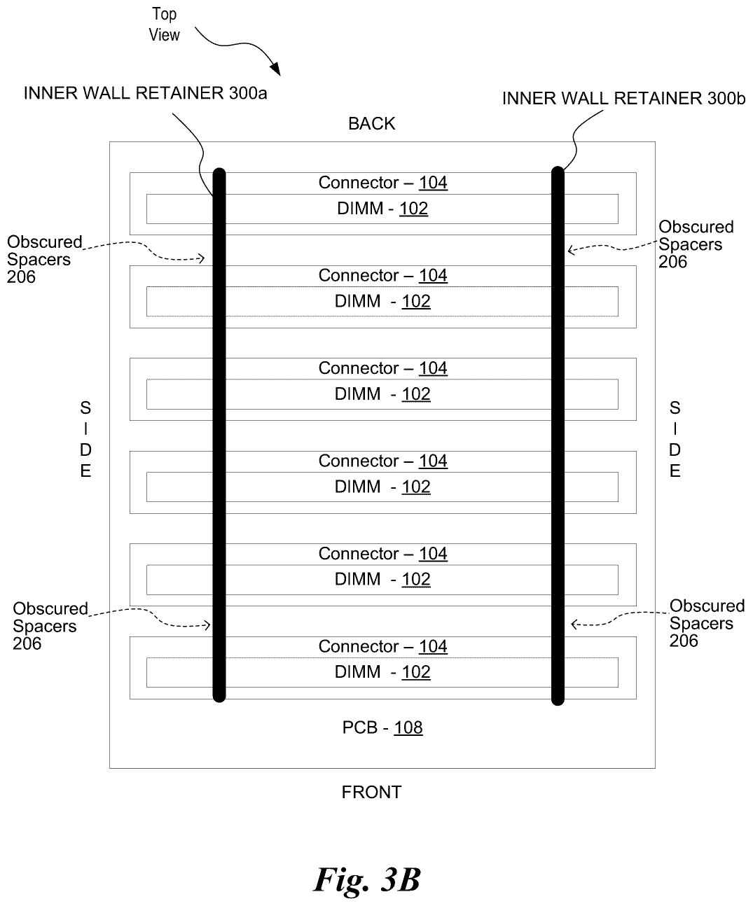

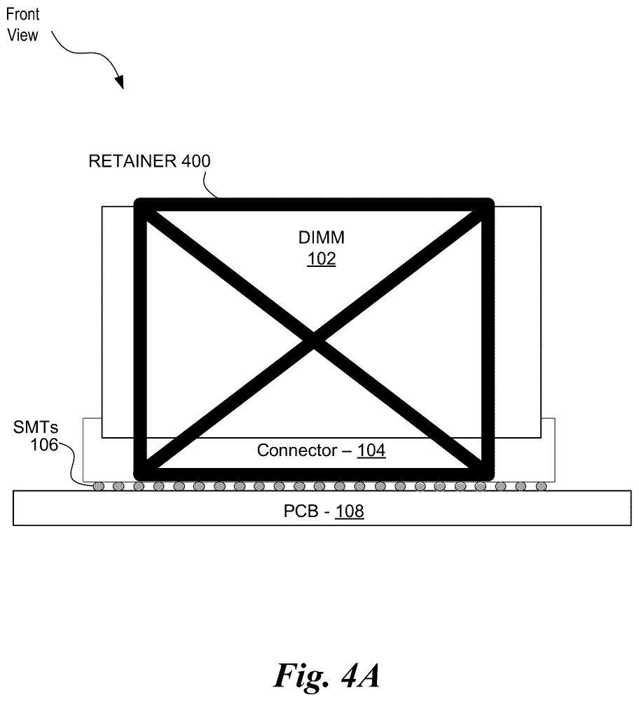

FIG. 3A illustrates an embodiment of another retainer 300 formed in accordance with embodiments described herein. As shown, the retainer 300 includes two vertical members and one horizontal member joined together to form a double T-shaped retainer. In this manner the horizontal member of retainer 300 extends over at least a portion of the top edges of each of the DIMMs 102 inserted into the connectors 104 to constrain the top edges, thereby inhibiting movement of the DIMMs 102 inserted into the connectors 104 during operation of the system.

The illustrated retainer in FIG. 3A is referred to as an inner wall retainer 300 because the vertical members attach to the inner surfaces of the outermost connectors 104 of multiple adjacent connectors 104. In one embodiment, the retainer 300 is attached to the inner surfaces of the outermost connectors 104 using pairs of spacers 206a/206b and 206c/206d. The spacers enable the vertical members of the retainer 300 to attach to the connectors 104 using friction and/or tension. In other words, the vertical members are wedged into the desired attachment location using the spacers to provide sufficient friction or tension to hold them in place during operation of the system.

FIG. 3B illustrates a top view of one example of two inner wall retainers 300a/300b disposed over multiple adjacent connectors 104. As shown, the horizontal members of both inner wall retainers 300a/300b extend over the vertical members held in place by the obscured spacers 206. The horizontal members also extend over at least a portion of the top edges of each of the DIMMs 102 inserted into the connectors 104 to constrain the top edges at each end of the connectors 104, thereby inhibiting movement of the DIMMs 102 inserted into the connectors 104 during operation of the system. Such an arrangement of multiple retainers 300 further constrains the top edges to inhibit movement of the DIMMs 102.

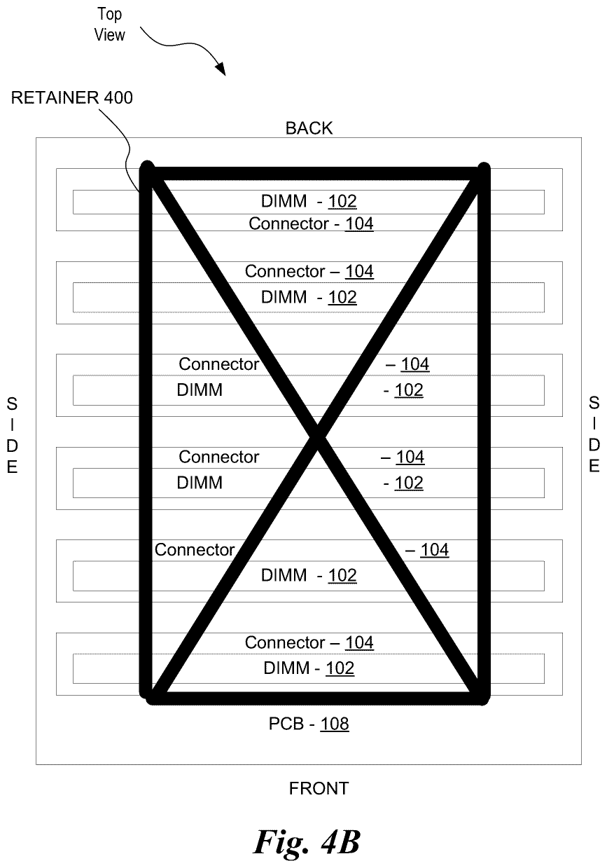

FIG. 4A illustrates a front view of another retainer 400 formed in accordance with embodiments described herein. As shown, the retainer 400 is a reinforced retainer that includes multiple vertical members and horizontal members joined together to form a frame around the multiple DIMMs 102 inserted into the connectors 104. In one embodiment, the retainer 400 frame is shaped into an open cubed-shaped frame spanning a length, width and depth of the multiple DIMMs 102 inserted into the respective multiple adjacent connectors 104. In one embodiment, the reinforced retainer 400 is capable of inhibiting the movement of multiple DIMMs 102 inserted into the respective multiple adjacent connectors 104.

In one embodiment, as shown in the front view in FIG. 4A, the vertical members are joined together with both horizontal members and oblique, or diagonal, members. As shown in the top view in FIG. 4B, the top horizontal members are also joined together with oblique, or diagonal members extending over the top edges of each of the DIMMs 102 inserted into the connectors 104. The oblique, or diagonal members serve to further constrain the top edges, thereby inhibiting movement of the DIMMs 102 inserted into the respective multiple adjacent connectors 104 during operation of the system.

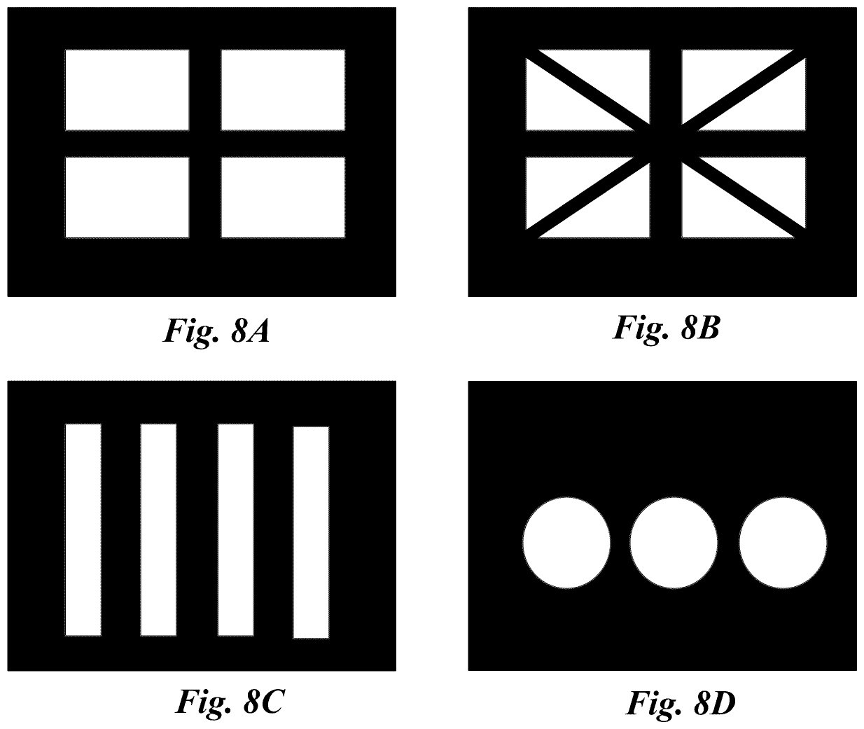

In one embodiment, the illustrated retainer 400 in FIGS. 4A/4B is reinforced with the additional horizontal and oblique members in a manner that still permits airflow through the DIMMs 102 and connectors 104. In one embodiment, the vertical members joined with the additional horizontal and oblique members form a cutout pattern of open areas to allow airflow over otherwise constrained top edges of the one or more DIMMs 102 inserted into the multiple adjacent connectors 104. Examples of various cutout patterns is illustrated in FIGS. 8A-8D, infra.

In one embodiment, the illustrated retainer 400 in FIGS. 4A/4B is attached to the outer surfaces of the outermost connectors 104 at locations on one or more of the vertical and horizontal reinforcing members to further strengthen the reinforced retainer 400.

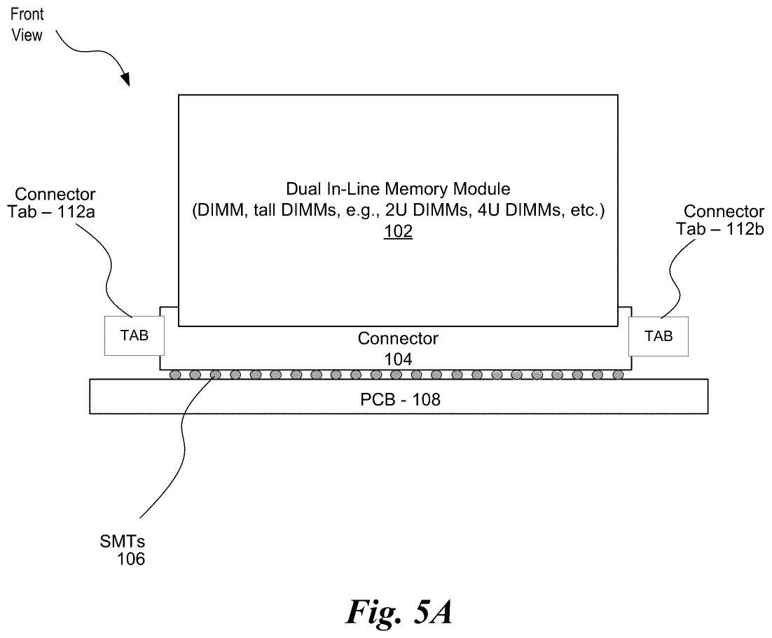

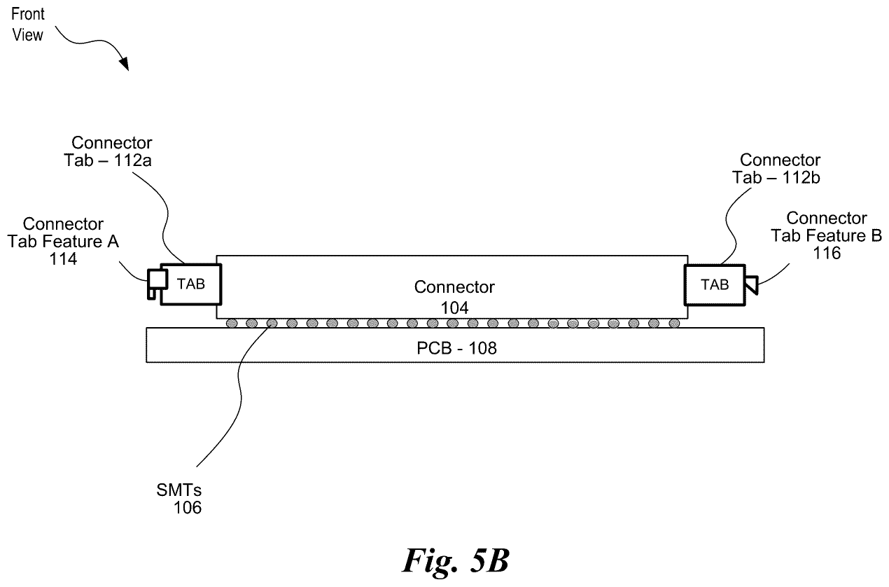

Turning now to the example embodiment illustrated in FIG. 5A, a connector 104 is augmented with connector tabs 112a/112b located at each end of the connector. The connector tabs 112a/112b facilitate the attachment of a retainer to the connector 104 in accordance with embodiments described herein.

As illustrated in FIG. 5B, the connector tabs 112a/112b can include one or more features to facilitate attachment to the connector 104, including a clip feature A 114 and a cleat feature B 116. Other connector tab features can be employed to facilitate attachment between the retainer and the connector 104. In one embodiment, the attachment ends of members of a retainer can be shaped to complement the connector tab feature 114/116 to facilitate attachment to as well as detachment from the connector 104.

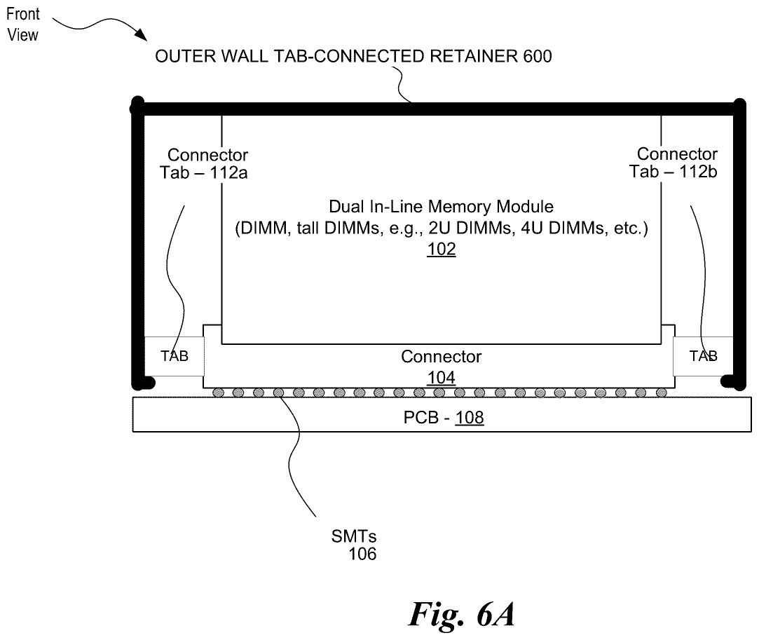

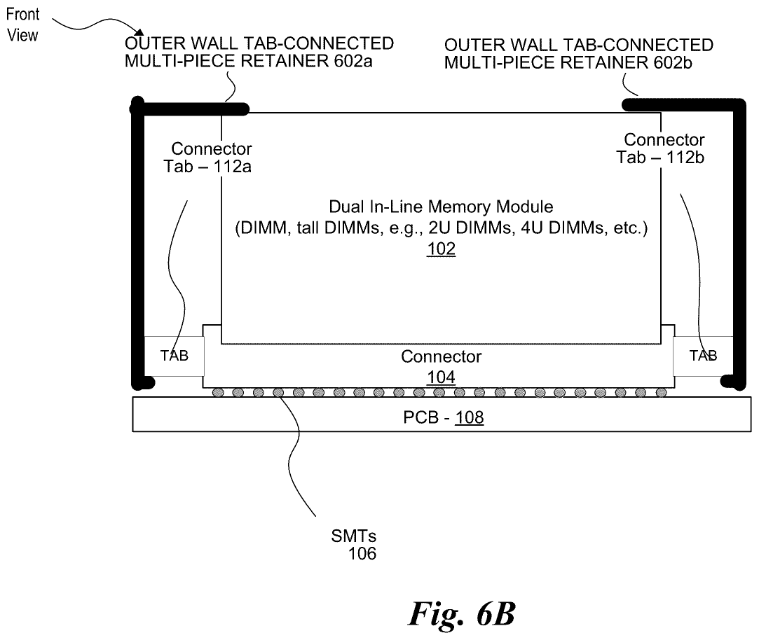

FIG. 6A illustrates an embodiment of another retainer 600 formed in accordance with embodiments described herein. As shown, the retainer 600 includes two vertical members and one horizontal member joined together to form a U-shaped bracket retainer, similar to the retainer 200 described supra in FIG. 2A, but extending over a single DIMM 102.

The illustrated retainer in FIG. 6A is referred to as an outer wall tab-connected retainer 600 because the vertical members attach to the outer surface of the ends of a tabbed connector 104 using the connector tabs 112a/112b. In this manner the horizontal member of retainer 600 extends over the top edge of a DIMM 102 inserted into the tabbed connector 104 to constrain the top edge, thereby inhibiting movement of the DIMM 102 inserted into the tabbed connector 104 during operation of the system.

In FIG. 6B, an embodiment of a multi-piece retainer 602a/602b is illustrated. Similar to retainer 600, the multipiece retainer extends over a single DIMM 102 which, in this case, is inserted into a tabbed connector 104. A horizontal member extends partially over the top edge of the single DIMM 102 to form an angled bracket-shaped retainer. The multi-piece retainer thus comprises two right-angled brackets 602a/602b disposed over the top edge of the single DIMM opposite to one another. The multi-piece retainer 602a/602b allows for more flexibility in placing the retainers over the DIMM 102 inserted into the tabbed connector 104.

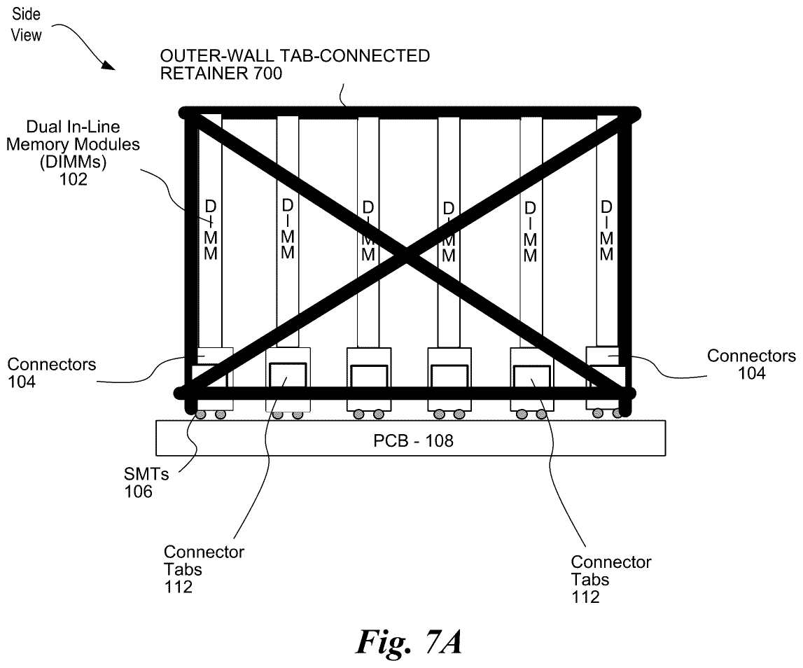

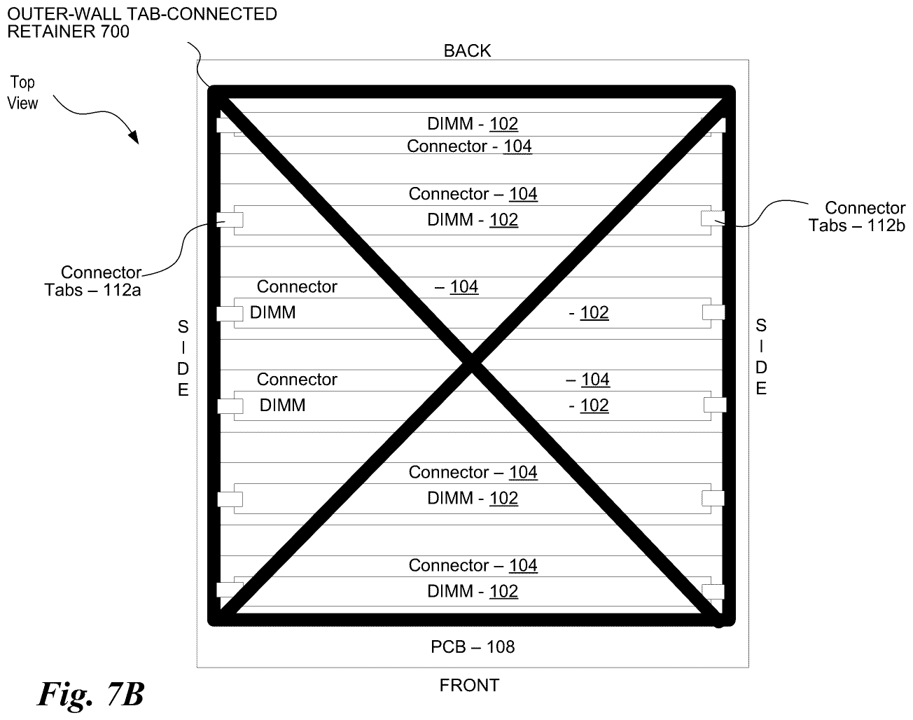

FIG. 7A illustrates a side view of another retainer 700 formed in accordance with embodiments described herein. As shown, the retainer 700 is a reinforced retainer that includes two vertical members, two horizontal members and two diagonal members joined together to form a frame around the multiple DIMMs 102 inserted into respective multiple adjacent tabbed connectors 104. In one embodiment, the retainer 700 frame is shaped into an open cubed-shaped frame spanning a length, width and depth of the multiple DIMMs 102 inserted into the respective multiple adjacent tabbed connectors 104. In one embodiment, the reinforced retainer 700 is capable of inhibiting the movement of multiple DIMMs 102 inserted into the respective multiple adjacent connectors 104.

In one embodiment, as shown in the side view in FIG. 7A, the top horizontal member reinforces the retainer 700 frame to support the diagonal members extending over the top edges of the DIMMs (not shown, see FIG. 7B). The lower horizontal member reinforces the attachment of the vertical members to the multiple adjacent tabbed connectors 104.

In one embodiment, the illustrated retainer 700 in FIG. 7A is reinforced with the additional horizontal and diagonal members in a manner that still permits airflow through the retained DIMMs 102 and the respective multiple adjacent tabbed connectors 104 into which the DIMMs 102 are inserted.

FIG. 7B illustrates a top view of retainer 700 formed in accordance with embodiments described herein. In one embodiment, instead of horizontal members extending over the DIMMs 102, the diagonal members extend over at least a portion of the top edges of the DIMMs 102 to constrain the top edges, thereby inhibiting movement of a DIMM 102 inserted into a tabbed connector 104 during operation of the system.

In one embodiment, the horizontal and diagonal members of retainer 700 form a cutout pattern of open areas to allow airflow over otherwise constrained top edges of the one or more DIMM 102 inserted into the respective multiple adjacent tabbed connectors 104. Examples of various cutout patterns is illustrated in FIGS. 8A-8D, infra.

In one embodiment, the illustrated retainer 700 in FIGS. 7A/7B is attached to the outer surfaces of the outermost connectors 104 at locations on one or more of both the vertical and horizontal reinforcing members to further strengthen the reinforced retainer 700.

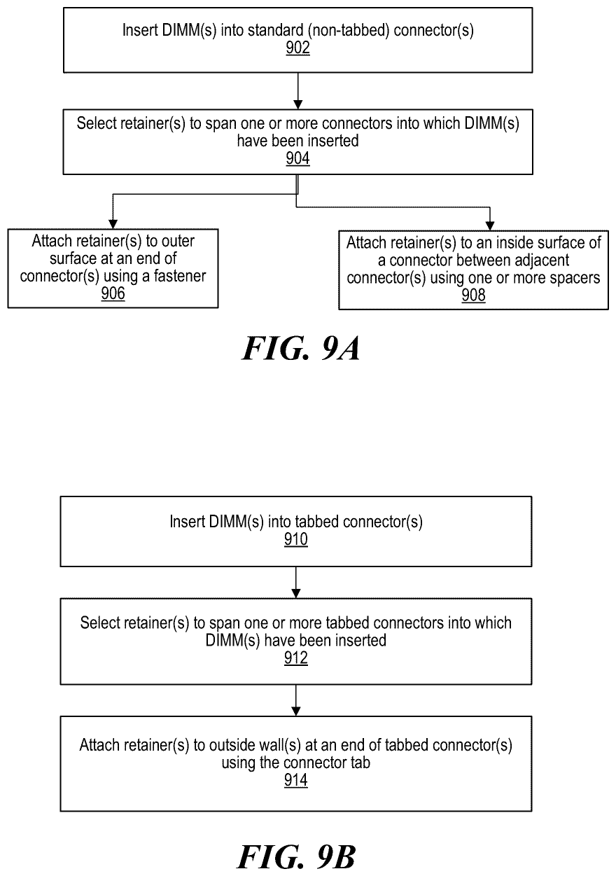

FIGS. 9A-9B are flow diagrams illustrating example processes for implementing a DIMM retainer in accordance with embodiments described herein.

FIG. 9A depicts an example process for implementing a DIMM retainer into standard (non-tabbed) connectors. In one embodiment, at process 902, DIMMs are inserted into one or more standard non-tabbed connectors. At process 904, retainers are selected to span one or more connectors into which DIMMs have been inserted. In one embodiment, at process 906, vertical member(s) of the retainer are attached to an outer surface at an end of a connector using a fastener. Alternatively, in one embodiment, at process 908, the retainer's vertical members are attached to an inside surface of a connector, including between adjacent connectors using one or more spacers.

FIG. 9B depicts an example process for implementing a DIMM retainer into tabbed connectors formed in accordance with embodiments described herein. In one embodiment, at process 910, DIMMs are inserted into one or more respective tabbed connectors. At process 912, retainers are selected to span the one or more respective tabbed connectors into which the DIMMs have been inserted. In one embodiment, at process 914, the retainer's vertical members are attached to an outside surface at an end of a tabbed connector using the connector tab.

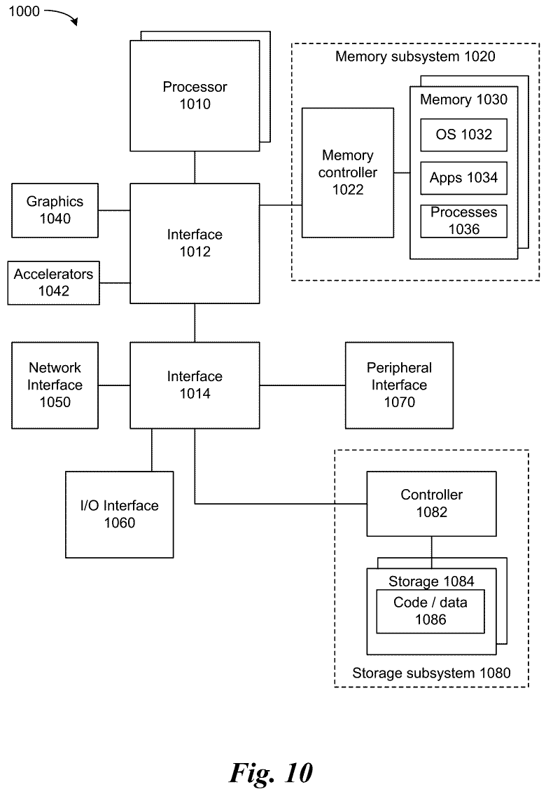

FIG. 10 depicts a system in which a DIMM retainer may be implemented in accordance with embodiments described herein. System 1000 includes processor 1010, which provides processing, operation management, and execution of instructions for system 1000. Processor 1010 can include any type of microprocessor, central processing unit (CPU), graphics processing unit (GPU), XPU, processing core, or other processing hardware to provide processing for system 1000, or a combination of processors. An XPU can include one or more of: a CPU, a graphics processing unit (GPU), general purpose GPU (GPGPU), and/or other processing units (e.g., accelerators or programmable or fixed function FPGAs). Processor 1010 controls the overall operation of system 1000, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, system 1000 includes interface 1012 coupled to processor 1010, which can represent a higher speed interface or a high throughput interface for system components that needs higher bandwidth connections, such as memory subsystem 1020 or graphics interface components 1040, or accelerators 1042. Interface 1012 represents an interface circuit, which can be a standalone component or integrated onto a processor die. Where present, graphics interface 1040 interfaces to graphics components for providing a visual display to a user of system 1000. In one example, graphics interface 1040 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 1040 generates a display based on data stored in memory 1030 or based on operations executed by processor 1010 or both. In one example, graphics interface 1040 generates a display based on data stored in memory 1030 or based on operations executed by processor 1010 or both.

Accelerators 1042 can be a programmable or fixed function offload engine that can be accessed or used by a processor 1010. For example, an accelerator among accelerators 1042 can provide compression (DC) capability, cryptography services such as public key encryption (PKE), cipher, hash/authentication capabilities, decryption, or other capabilities or services. In some embodiments, in addition or alternatively, an accelerator among accelerators 1042 provides field select controller capabilities as described herein. In some cases, accelerators 1042 can be integrated into a CPU socket (e.g., a connector to a motherboard or circuit board that includes a CPU and provides an electrical interface with the CPU). For example, accelerators 1042 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs). Accelerators 1042 can provide multiple neural networks, CPUs, processor cores, general purpose graphics processing units, or graphics processing units can be made available for use by artificial intelligence (AI) or machine learning (ML) models. For example, the AI model can use or include any or a combination of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 1020 represents the main memory of system 1000 and provides storage for code to be executed by processor 1010, or data values to be used in executing a routine. Memory subsystem 1020 can include one or more memory devices 1030 such as read-only memory (ROM), flash memory, one or more varieties of random access memory (RAM) such as DRAM, or other memory devices, or a combination of such devices. Memory 1030 stores and hosts, among other things, operating system (OS) 1032 to provide a software platform for execution of instructions in system 1000. Additionally, applications 1034 can execute on the software platform of OS 1032 from memory 1030. Applications 1034 represent programs that have their own operational logic to perform execution of one or more functions. Processes 1036 represent agents or routines that provide auxiliary functions to OS 1032 or one or more applications 1034 or a combination. OS 1032, applications 1034, and processes 1036 provide software logic to provide functions for system 1000. In one example, memory subsystem 1020 includes memory controller 1022, which is a memory controller to generate and issue commands to memory 1030. It will be understood that memory controller 1022 could be a physical part of processor 1010 or a physical part of interface 1012. For example, memory controller 1022 can be an integrated memory controller, integrated onto a circuit with processor 1010.

While not specifically illustrated, it will be understood that system 1000 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a Hyper Transport or industry standard architecture (ISA) bus, a small computer system interface (SCSI) bus, a universal serial bus (USB), or an Institute of Electrical and Electronics Engineers (IEEE) standard 1394 bus (Firewire).

In one example, system 1000 includes interface 1014, which can be coupled to interface 1012. In one example, interface 1014 represents an interface circuit, which can include standalone components and integrated circuitry. In one example, multiple user interface components or peripheral components, or both, couple to interface 1014. Network interface 1050 provides system 1000 with the ability to communicate with remote devices (e.g., servers or other computing devices) over one or more networks. Network interface 1050 can include an Ethernet adapter, wireless interconnection components, cellular network interconnection components, USB (universal serial bus), or other wired or wireless standards-based or proprietary interfaces. Network interface 1050 can transmit data to a device that is in the same data center or rack or a remote device, which can include sending data stored in memory. Network interface 1050 can receive data from a remote device, which can include storing received data into memory. Various embodiments can be used in connection with network interface 1050, processor 1010, and memory subsystem 1020.

In one example, system 1000 includes one or more input/output (I/O) interface(s) 1060. I/O interface 1060 can include one or more interface components through which a user interacts with system 1000 (e.g., audio, alphanumeric, tactile/touch, or other interfacing). Peripheral interface 1070 can include any hardware interface not specifically mentioned above. Peripherals refer generally to devices that connect dependently to system 1000. A dependent connection is one where system 1000 provides the software platform or hardware platform or both on which operation executes, and with which a user interacts.

In one example, system 1000 includes storage subsystem 1080 to store data in a nonvolatile manner. In one example, in certain system implementations, at least certain components of storage 1080 can overlap with components of memory subsystem 1020. Storage subsystem 1080 includes storage device(s) 1084, which can be or include any conventional medium for storing large amounts of data in a nonvolatile manner, such as one or more magnetic, solid state, or optical based disks, or a combination. Storage 1084 holds code or instructions and data 1086 in a persistent state (e.g., the value is retained despite interruption of power to system 1000). Storage 1084 can be generically considered to be a “memory,” although memory 1030 is typically the executing or operating memory to provide instructions to processor 1010. Whereas storage 1084 is nonvolatile, memory 1030 can include volatile memory (e.g., the value or state of the data is indeterminate if power is interrupted to system 1000). In one example, storage subsystem 1080 includes controller 1082 to interface with storage 1084. In one example controller 1082 is a physical part of interface 1014 or processor 1010 or can include circuits or logic in both processor 1010 and interface 1014.

A volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). Another example of volatile memory includes cache or static random access memory (SRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/output version 2, JESD229-2 originally published by JEDEC in August 2014, HBM (High Bandwidth Memory, JESD325, originally published by JEDEC in October 2013, LPDDR5 (currently in discussion by JEDEC), HBM2 (HBM version 2), currently in discussion by JEDEC, or others or combinations of memory technologies, and technologies based on derivatives or extensions of such specifications. The JEDEC standards are available at www.jedec.org.

A non-volatile memory (NVM) device is a memory whose state is determinate even if power is interrupted to the device. In some embodiments, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), Intel® Optane™ memory, NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

A power source (not depicted) provides power to the components of system 1000. More specifically, power source typically interfaces to one or multiple power supplies in system 1000 to provide power to the components of system 1000. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 1000 can be implemented using interconnected compute sleds of processors, memories, storages, network interfaces, and other components. High speed interconnects can be used such as PCIe, Ethernet, or optical interconnects (or a combination thereof).

Embodiments herein may be implemented in various types of computing and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation. It is noted that hardware, firmware and/or software elements may be collectively or individually referred to herein as “module,” or “logic.” A processor can be one or more combination of a hardware state machine, digital control logic, central processing unit, or any hardware, firmware and/or software elements.

Some examples may be implemented using or as an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

One or more aspects of at least one example may be implemented by representative instructions stored on at least one machine-readable medium which represents various logic within the processor, which when read by a machine, computing device or system causes the machine, computing device or system to fabricate logic to perform the techniques described herein. Such representations, known as “IP cores” may be stored on a tangible, machine readable medium and supplied to various customers or manufacturing facilities to load into the fabrication machines that actually make the logic or processor.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences of steps may also be performed according to alternative embodiments. Furthermore, additional steps may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”’

Flow diagrams as illustrated herein provide examples of sequences of various process actions. The flow diagrams can indicate operations to be executed by a software or firmware routine, as well as physical operations. In some embodiments, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, and so forth.

Illustrative examples of the devices, systems, and methods disclosed herein are provided below. An embodiment of the devices, systems, and methods may include any one or more, and any combination of, the examples described below.

Example 1 is a method, system, apparatus or computer-readable medium in which an embodiment of a DIMM retainer comprises connectors to connect dual in-line memory modules (DIMMs) to a printed circuit board (PCB) of a system, one or more vertical members to attach to the connectors, at least one horizontal member joined to a top portion of at least one of the one or more vertical members, the horizontal member to constrain a top edge of one or more of the DIMMs inserted into the connectors, and wherein joined members form a retainer to inhibit movement of the DIMMs inserted into the connectors during operation of the system.

Example 2 is the method, system, apparatus or computer-readable medium as in Example 1, wherein a shape of the retainer includes any of a U-shaped bracket or a T-shaped bracket, a bracket including two vertical members attached to opposite ends of a single connector and one horizontal member extending between the two vertical members along the top edge of one DIMM inserted into the single connector, and a right-angled bracket, including a single vertical member attached to one end of the single connector and one horizontal member extending along at least a portion of the top edge of the one DIMM inserted into the single connector.

Example 3 is the method, system, apparatus or computer-readable medium as in any of Examples 1 and 2, wherein a shape of the retainer includes a frame comprising pairs of vertical members attached to pairs of the connectors, the pairs of the connectors delimiting multiple adjacent connectors, and one or more horizontal members joined to the pairs of vertical members, the horizontal members to constrain a top edge of one or more DIMMs inserted into the multiple adjacent connectors.

Example 4 is the method, system, apparatus or computer-readable medium as in any of Examples 1, 2 and 3, wherein the frame further comprises any of one or more oblique members joined to vertical members to reinforce the frame while allowing airflow to otherwise retained DIMMs inserted into the connectors, including a diagonal member joined to corresponding same-sided vertical members of the pairs of vertical members, and one or more horizontal members joined to vertical members to reinforce a bottom portion of the frame, including alongside the connectors from one end of vertical member attachment to a corresponding same-sided end of another vertical member attachment.

Example 5 is the method, system, apparatus or computer-readable medium as in any of Examples 1, 2, 3 and 4, wherein the one or more horizontal members joined to the pairs of vertical members form a cutout pattern of open areas on one or more sides of the frame to allow airflow over otherwise constrained top edges of the one or more DIMMs inserted into the multiple adjacent connectors.

Example 6 is the method, system, apparatus or computer-readable medium as in any of Examples 1, 2, 3, 4 and 5, further comprising attachment hardware, including any one or more of fasteners to attach the one or more vertical members to an outer surface of the connectors, including any of a threaded screw to tighten a spring compressive pin against the outer surface, and spacers to attach the one or more vertical members to an inner surface of the connectors, including to wedge a vertical member between two adjacent connectors using the spacers.

Example 7 is the method, system, apparatus or computer-readable medium as in any of Examples 1, 2, 3, 4, 5 and 6, further comprising tabbed connectors, a tabbed connector having a tab extension at one or both ends of a connector, and wherein the tab extension includes a feature that enables a vertical member to be removably attached to an outer surface of the connector without using attachment hardware.

Example 8 is the method, system, apparatus or computer-readable medium as in any of Examples 1, 2, 3, 4, 5, 6 and 7, wherein the DIMM includes tall DIMMs for use in multiple rack unit (RU) servers, including any of 2 U DIMMS, 4 U DIMMS and higher height DIMMs.

Example 9 is a method, system, apparatus or computer-readable medium in which an embodiment of a DIMM retainer comprising a chassis to house connectors mounted to a printed circuit board (PCB) using surface mount technology pads (SMTs), one or more vertical members to attach to the connector at least one horizontal member joined to a top portion of at least one of the one or more vertical members, the horizontal member to constrain a top edge of one or more dual in-line memory modules (DIMMs) inserted into the connectors, and wherein joined members form a retainer to inhibit movement of the DIMMs inserted into the connectors during operation without impacting the chassis.

Example 10 is the method, system, apparatus or computer-readable medium as in Example 9, wherein a shape of the retainer includes any of a U-shaped bracket or a T-shaped bracket, a bracket including two vertical members attached to opposite ends of a single connector and one horizontal member extending between the two vertical members along the top edge of one DIMM inserted into the single connector, and a right-angled bracket, including a single vertical member attached to one end of the single connector and one horizontal member extending along at least a portion of the top edge of the one DIMM inserted into the single connector.

Example 11 is the method, system, apparatus or computer-readable medium as in any of Examples 9 and 10, wherein a shape of the retainer is a frame comprising pairs of vertical members attached to pairs of the connectors, the pairs of the connectors delimiting multiple adjacent connectors, and one or more horizontal members joined to the pairs of vertical members, the horizontal members to constrain a top edge of the one or more DIMMs inserted into the multiple adjacent connectors.

Example 12 is the method, system, apparatus or computer-readable medium as in any of Examples 9, 10 and 11, wherein the frame further comprises any o one or more oblique members joined to vertical members to reinforce the frame while allowing airflow to otherwise retained DIMMs inserted into the connectors, including a diagonal member joined to corresponding same-sided vertical members of the pairs of vertical members, and one or more horizontal members joined to vertical members to reinforce a bottom portion of the frame, including alongside the connectors from one end of a vertical member attachment to a corresponding same-sided end of another vertical member attachment.

Example 13 is the method, system, apparatus or computer-readable medium as in any of Examples 9, 10, 11 and 12, wherein the one or more horizontal members joined to the pairs of vertical members form a cutout pattern of open areas to allow airflow over otherwise constrained top edges of the one or more DIMMs inserted into the multiple adjacent connectors.

Example 14 is the method, system, apparatus or computer-readable medium as in any of Examples 9, 10, 11, 12 and 13, further comprising attachment hardware, including any one or more of fasteners to attach the one or more vertical members to an outer surface of the connectors, including any of a threaded screw to tighten a spring compressive pin against the outer surface, and further including spacers to attach the one or more vertical members to an inner surface of the connectors, including to wedge a vertical member between two adjacent connectors using the spacers.

Example 15 is the method, system, apparatus or computer-readable medium as in any of Examples 9, 10, 11, 12, 13 and 14, further comprising tabbed connectors, a tabbed connector having a tab extension at one or both ends of a connector, and wherein the tab extension includes a feature that enables a vertical member to be removably attached to an outer surface of the connector without using attachment hardware.

Example 16 is the method, system, apparatus or computer-readable medium as in any of Examples 9, 10, 11, 12, 13, 14 and 15, wherein the DIMM includes tall DIMMs for use in multiple rack unit (RU) servers, including any of 2 U DIMMS, 4 U DIMMS and higher height DIMMs.

Example 17 is a method, system, apparatus or computer-readable medium in which an embodiment of a dual in-line memory module (DIMM) retainer comprises one or more vertical members capable of attachment to one or more connectors mounted to a printed circuit board (PCB), at least one horizontal member joined to a top portion of at least one of the one or more vertical members, the horizontal member to constrain a top edge of one or more DIMMs inserted into the one or more connectors, and wherein joined members inhibit movement of the one or more DIMMS inserted into the one or more connectors.

Example 18 is the method, system, apparatus or computer-readable medium as in Example 17, wherein a shape of the retainer includes any of a U-shaped bracket or a T-shaped bracket, a bracket including two vertical members attached to opposite ends of a single connector and one horizontal member extending between the two vertical members along the top edge of one DIMM inserted into the single connector, and a right-angled bracket, including a single vertical member attached to one end of the single connector and one horizontal member extending along at least a portion of the top edge of the one DIMM inserted into the single connector.

Example 19 is the method, system, apparatus or computer-readable medium as in any of Examples 17 and 18, wherein a shape of the retainer includes a frame comprising pairs of vertical members attached to pairs of the connectors, the pairs of the connectors delimiting multiple adjacent connectors, and one or more horizontal members joined to the pairs of vertical members, the horizontal members to constrain a top edge of one or more DIMMs inserted into the multiple adjacent connectors.

Example 20 is the method, system, apparatus or computer-readable medium as in any of Examples 17, 18 and 19, wherein the DIMMs include tall DIMMs for use in multiple rack unit (RU) servers, including any of 2 U DIMMS, 4 U DIMMS and higher height DIMMs and the joined members are composed of a rigid material, including any of a plastic material and a metal material.

What is claimed is:

1. An apparatus comprising:
connectors to connect dual in-line memory modules (DIMMs) to a printed circuit board (PCB) of a system;
one or more vertical members to attach to the connectors;
at least one horizontal member joined to a top portion of at least one of the one or more vertical members, the horizontal member to constrain a top edge of one or more of the DIMMs inserted into the connectors; and
wherein joined members form a retainer to inhibit movement of the DIMMs inserted into the connectors during operation of the system.

2. The apparatus of claim 1, wherein a shape of the retainer includes any of:
a U-shaped bracket or a T-shaped bracket, a bracket including two vertical members attached to opposite ends of a single connector and one horizontal member extending between the two vertical members along the top edge of one DIMM inserted into the single connector; and
a right-angled bracket, including a single vertical member attached to one end of the single connector and one horizontal member extending along at least a portion of the top edge of the one DIMM inserted into the single connector.

3. The apparatus of claim 1, wherein a shape of the retainer includes a frame comprising:
pairs of vertical members attached to pairs of the connectors, the pairs of the connectors delimiting multiple adjacent connectors; and
one or more horizontal members joined to the pairs of vertical members, the horizontal members to constrain a top edge of one or more DIMMs inserted into the multiple adjacent connectors.

4. The apparatus of claim 3, wherein the frame further comprises any of:
one or more oblique members joined to vertical members to reinforce the frame while allowing airflow to otherwise retained DIMMs inserted into the connectors, including a diagonal member joined to corresponding same-sided vertical members of the pairs of vertical members; and
one or more horizontal members joined to vertical members to reinforce a bottom portion of the frame, including alongside the connectors from one end of vertical member attachment to a corresponding same-sided end of another vertical member attachment.

5. The apparatus of claim 3, wherein the one or more horizontal members joined to the pairs of vertical members form a cutout pattern of open areas on one or more sides of the frame to allow airflow over otherwise constrained top edges of the one or more DIMMs inserted into the multiple adjacent connectors.

6. The apparatus of claim 1, further comprising attachment hardware, including any one or more of:
fasteners to attach the one or more vertical members to an outer surface of the connectors, including any of a threaded screw to tighten a spring compressive pin against the outer surface; and
spacers to attach the one or more vertical members to an inner surface of the connectors, including to wedge a vertical member between two adjacent connectors using the spacers.

7. The apparatus of claim 1, further comprising:
tabbed connectors, a tabbed connector having a tab extension at one or both ends of a connector; and
wherein the tab extension includes a feature that enables a vertical member to be removably attached to an outer surface of the connector without using attachment hardware.

8. The apparatus of claim 1, wherein the DIMM includes tall DIMMs for use in multiple rack unit (RU) servers, including any of 2 U DIMMS, 4 U DIMMS and higher height DIMMs.

9. A system comprising:
a chassis to house connectors mounted to a printed circuit board (PCB) using surface mount technology pads (SMTs);
one or more vertical members to attach to the connectors;
at least one horizontal member joined to a top portion of at least one of the one or more vertical members, the horizontal member to constrain a top edge of one or more dual in-line memory modules (DIMMs) inserted into the connectors; and
wherein joined members form a retainer to inhibit movement of the DIMMs inserted into the connectors during operation without impacting the chassis.

10. The system of claim 9, wherein a shape of the retainer includes any of:
a U-shaped bracket or a T-shaped bracket, a bracket including two vertical members attached to opposite ends of a single connector and one horizontal member extending between the two vertical members along the top edge of one DIMM inserted into the single connector; and
a right-angled bracket, including a single vertical member attached to one end of the single connector and one horizontal member extending along at least a portion of the top edge of the one DIMM inserted into the single connector.

11. The system of claim 9, wherein a shape of the retainer is a frame comprising:
pairs of vertical members attached to pairs of the connectors, the pairs of the connectors delimiting multiple adjacent connectors; and
one or more horizontal members joined to the pairs of vertical members, the horizontal members to constrain a top edge of the one or more DIMMs inserted into the multiple adjacent connectors.

12. The system of claim 11, wherein the frame further comprises any of:
one or more oblique members joined to vertical members to reinforce the frame while allowing airflow to otherwise retained DIMMs inserted into the connectors, including a diagonal member joined to corresponding same-sided vertical members of the pairs of vertical members; and
one or more horizontal members joined to vertical members to reinforce a bottom portion of the frame, including alongside the connectors from one end of a vertical member attachment to a corresponding same-sided end of another vertical member attachment.

13. The system of claim 11, wherein the one or more horizontal members joined to the pairs of vertical members form a cutout pattern of open areas to allow airflow over otherwise constrained top edges of the one or more DIMMs inserted into the multiple adjacent connectors.

14. The system of claim 9, further comprising attachment hardware, including any one or more of:
fasteners to attach the one or more vertical members to an outer surface of the connectors, including any of a threaded screw to tighten a spring compressive pin against the outer surface; and
spacers to attach the one or more vertical members to an inner surface of the connectors, including to wedge a vertical member between two adjacent connectors using the spacers.

15. The system of claim 9, further comprising:
tabbed connectors, a tabbed connector having a tab extension at one or both ends of a connector; and
wherein the tab extension includes a feature that enables a vertical member to be removably attached to an outer surface of the connector without using attachment hardware.

16. The system of claim 9, wherein the DIMM includes tall DIMMs for use in multiple rack unit (RU) servers, including any of 2 U DIMMS, 4 U DIMMS and higher height DIMMs.

17. A dual in-line memory module (DIMM) retainer comprising:
one or more vertical members capable of attachment to one or more connectors mounted to a printed circuit board (PCB);
at least one horizontal member joined to a top portion of at least one of the one or more vertical members, the horizontal member to constrain a top edge of one or more DIMMs inserted into the one or more connectors; and
wherein joined members inhibit movement of the one or more DIMMS inserted into the one or more connectors.

18. The DIMM retainer of claim 17, wherein a shape of the retainer includes any of:
a U-shaped bracket or a T-shaped bracket, a bracket including two vertical members attached to opposite ends of a single connector and one horizontal member extending between the two vertical members along the top edge of one DIMM inserted into the single connector; and
a right-angled bracket, including a single vertical member attached to one end of the single connector and one horizontal member extending along at least a portion of the top edge of the one DIMM inserted into the single connector.

19. The DIMM retainer of claim 17, wherein a shape of the retainer includes a frame comprising:
pairs of vertical members attached to pairs of the connectors, the pairs of the connectors delimiting multiple adjacent connectors; and
one or more horizontal members joined to the pairs of vertical members, the horizontal members to constrain a top edge of one or more DIMMs inserted into the multiple adjacent connectors.

20. The DIMM retainer of claim 17, wherein any of:
the DIMM includes tall DIMMs for use in multiple rack unit (RU) servers, including any of 2 U DIMMS, 4 U DIMMS and higher height DIMMs; and
the joined members are composed of a rigid material, including any of a plastic material and a metal material.
